(19) United States
(12) Patent Application Publication
(10) Pub. No.: US 2015/0140690 A1
(43) Pub. Date: May 21, 2015

(54) ETCHING METHOD FOR SEMICONDUCTOR PRODUCT

(71) Applicants: Takeshi Sakai, Sendai-shi (JP); Tatsuro Yoshida, Sendai-shi (JP); Kazuhiro Yoshikawa, Sendai-shi (JP); Shigetoshi Sugawa, Sendai-shi (JP)

(72) Inventors: Takeshi Sakai, Sendai-shi (JP); Tatsuro Yoshida, Sendai-shi (JP); Kazuhiro Yoshikawa, Sendai-shi (JP); Shigetoshi Sugawa, Sendai-shi (JP)

(73) Assignee: TOHOKU UNIVERSITY, Sendai-shi (JP)

(21) Appl. No.: 14/564,227

(22) Filed: Dec. 9, 2014

Related U.S. Application Data
(63) Continuation of application No. PCT/JP2012/004870, filed on Jul. 31, 2012.

(51) Int. Cl. H01L 21/306; H01L 21/66

(52) U.S. Cl. CPC H01L 21/30604; H01L 22/26
USPC 438/5

(57) ABSTRACT

There is provided an etching method for a semiconductor product. The semiconductor product having, on a substrate, an SiO₂ layer, and an Si layer with a free surface and directly stacked on the SiO₂ layer is prepared. The Si layer is etched. Etching is performed while supplying an etching solution from a side of the free surface using high-concentration fluonitric acid as the etching solution, and etching is continued by switching to fluonitric acid having a concentration lower than that of the fluonitric acid immediately before or after at least part of a surface of the SiO₂ layer immediately under the Si layer is exposed.

This application is a continuation of International Patent Application No. PCT/JP2012/004870 filed on Jul. 31, 2012, the entire content of which is incorporated herein by reference.

### BACKGROUND OF THE INVENTION

1. Field of the Invention

The present invention relates to an etching method for a semiconductor product, which etches the upper surface of a silicon wafer or the like using an etching solution.

2. Description of the Related Art

A semiconductor apparatus using an SOI (Silicon on Insulator) substrate is generally advantageous in energy-saving and operation speed, as compared with a semiconductor apparatus using an Si substrate such as a silicon (Si) wafer. For example, in the area of a photoelectric conversion apparatus such as an image sensor, it has been proposed to use an SOI substrate.

On the other hand, along with an increase in number of opportunities to capture an image or observe an object at a high definition and high resolution, high-density image sensors are increasingly proposed/developed year by year. In a high-density image sensor, photoelectric conversion elements such as photodiodes are arrayed at high density to form a photoelectric conversion unit. As the density is higher, the area of the light-receiving surface (pixel) of the photoelectric conversion element has to become smaller. As the area of the light-receiving surface becomes smaller, an amount of light entering the photoelectric conversion element per unit time also becomes smaller and thus it is necessary to improve the light sensitivity of the photoelectric conversion element. However, improvement of the light sensitivity has limitations.

Furthermore, one of large factors which decrease the area of the light-receiving surface more than necessary along with an increase in density is an area occupied by wiring for transmitting a signal to each photoelectric conversion element or driving element, and applying a predetermined voltage to a predetermined position of the image sensor. In general, wiring is designed to have a wide width as much as possible to keep its resistance low for the convenience of manufacturing. For this reason, the ratio of an area occupied by wiring of a light-receiving unit including a plurality of two-dimensionally arrayed light-receiving surfaces increases as the density of the arrayed light-receiving surfaces is higher. To avoid this situation, it has been proposed and put into practical use to decrease the resistance by increasing the thickness of the wiring instead of its width. However, it causes an increase in number of manufacturing processes, resulting in an increase in cost.

In recent years, as a method of increasing the density and improving the light sensitivity, a number of so-called back-side illumination image sensors which cause light to enter in a direction (from the lower surface of an Si substrate) opposite to the incident direction to the photoelectric conversion unit of a general image sensor have been proposed since it is possible to reduce the influence of the wiring area, and some of the image sensors have been put into practical use. In this type of image sensors, a first substrate in which a photoelectric conversion unit is provided and a second substrate in which a driving circuit is provided on an SOI substrate are bonded so that a surface of the first substrate opposite to that on which the photoelectric conversion unit is provided faces a surface of the second substrate on which the driving circuit is provided.

Since, however, light enters the photoelectric conversion elements through the Si substrate, it is required to provide a measure for allowing light beams of respective colors (wavelengths) to efficiently enter the light-receiving surfaces of corresponding photoelectric conversion elements, respectively.

There is proposed one method of removing the lower surface of the Si substrate by CMP (Chemical Mechanical Polishing) or wet etching, so that the Si substrate becomes as thin as possible. However, since the Si substrate is relatively thick, it is conventionally ground by CMP to a predetermined thickness, and then undergoes wet etching to remove a so-called damage layer due to CMP. This requires a long time, and rate-determines the production efficiency, resulting in an increase in cost.

As the solution to this problem, it has been proposed to significantly improve the production efficiency using high-concentration fluonitric acid that is conventionally considered to be inappropriate for practical use as an etching solution (Japanese Patent Laid-Open No. 2012-119656).

### SUMMARY OF THE INVENTION

According to the first embodiment, an etching method for a semiconductor product comprises: preparing the semiconductor product having, on a substrate, an SiO₂ layer, and an Si layer with a free surface and directly stacked on the SiO₂ layer; and etching the Si layer while supplying an etching solution from a side of the free surface using high-concentration fluonitric acid as the etching solution, and continuing etching by switching to fluonitric acid having a concentration lower than that of the fluonitric acid immediately before or after at least part of a surface of the SiO₂ layer immediately under the Si layer is exposed.

According to the second embodiment, the etching method for the semiconductor product according to the first embodiment further comprises measuring a temperature at a plurality of predetermined positions on the surface during the etching; and heating or cooling the surface in accordance with the measured values.

According to the third embodiment, an etching method for a semiconductor product comprises: performing etching processing while supplying a fluonitric acid solution to a surface of an Si layer of the semiconductor product having, on a substrate, an SiO₂ layer and the Si layer with a free surface and directly stacked on the SiO₂ layer, the etching processing comprises: a first step of performing etching processing for the surface of the Si substrate using first fluonitric acid having a chemical composition of HF (a)-HNO₃ (b)-H₂O (c) (a+b+c=100 and a+b≧50 where a, b, and c are numerical values each representing a concentration, and the unit of a, b, and c is wt %) until a time immediately before or after at least part of the surface of the SiO₂ layer is exposed; and a second step of, after the first step, continuing etching processing using second fluonitric acid having a concentration lower than that of the first fluonitric acid.

According to the fourth embodiment, the etching method for the semiconductor product according to the third embodiment further comprises measuring a temperature at a plurality of predetermined positions on an etched surface of the Si layer during the etching processing; and heating or cooling the surface in accordance with the measured values.

According to the fifth embodiment, an etching method for a semiconductor product comprises: measuring a temperature at a plurality of predetermined positions on the surface during the etching processing in which an exothermic reaction occurs while supplying an etching solution to a surface of an Si layer of the semiconductor product having, on a substrate, an SiO₂ layer and the Si layer with a free surface and directly stacked on the SiO₂ layer; and heating or cooling the surface in accordance with the measured values, and switching from a high-concentration etching chemical solution to a low-concentration etching chemical solution immediately before or after at least part of the surface of the SiO₂ layer is exposed.

Other features and advantages of the present invention will be apparent from the following descriptions taken in conjunction with the accompanying drawings, in which like reference characters designate the same or similar parts throughout the figures thereof.

The accompanying drawings, which are incorporated in and constitute a part of the specification, illustrate embodiments of the invention and, together with the description, serve to explain the principles of the invention.

### BRIEF DESCRIPTION OF THE DRAWINGS

FIG. 1 is a schematic diagram for schematically explaining the problems of the related art;

FIG. 2 is a schematic view for explaining the main parts of an example of an etching apparatus according to the present invention;

FIG. 3 is a schematic view for explaining a typical example of an experimental result according to the present invention;

FIG. 4A is a schematic view for explaining a preferred example of the relationship between the etched surface of an Si substrate and a solution supply direction from a supply nozzle for supplying an etching solution to the etched surface according to the present invention;

FIG. 4B is a schematic view for explaining a preferred example of the relationship between the etched surface of the Si substrate and the solution supply direction from the supply nozzle for supplying the etching solution to the etched surface according to the present invention;

FIG. 5 is a graph for explaining an example of the temperature dependence of the etching rate;

FIG. 6 is a schematic view showing a preferred example of an etching apparatus for implementing the present invention;

FIG. 7 is a schematic view for explaining a preferred example of an etching system according to the present invention; and

FIG. 8 is a schematic view for explaining the main parts of another etching apparatus according to the present invention.

### DESCRIPTION OF THE EMBODIMENTS

The inventors of the present application confirmed the following problems as a result of conducting a further experiment for the technique described in PLT 1.

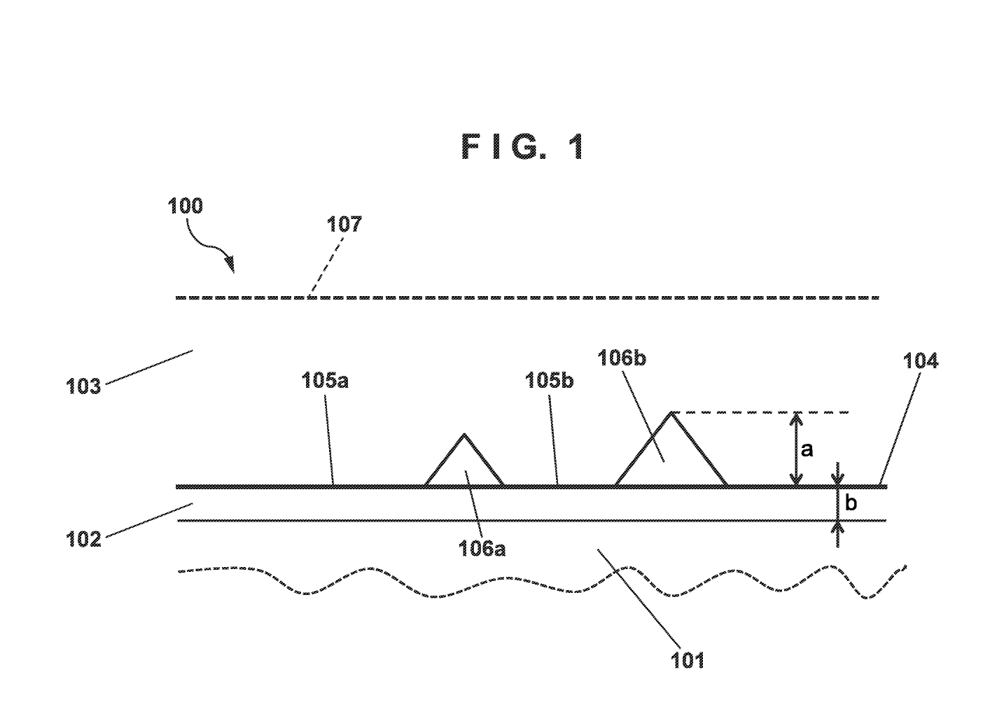

That is, referring to FIG. 1, the etching rate of a fluonitric acid chemical solution for Si is very high and its concentration dependence is not small. Thus, if the area of an etched surface is large, position-dependent nonuniformity in concentration of the etching chemical solution on the etched surface may occur to cause uneven etching progress, resulting in an Si convex portion (remaining portion) 106 as an etching residue on a surface 104 of an SiO₂ layer. If, therefore, the thickness b of an SiO₂ layer 102 is much smaller than a maximum height a of the Si convex portion (remaining portion) 106, the whole SiO₂ layer 102 is etched and removed on an exposed surface portion 105 of the SiO₂ layer, which has already been exposed, before the whole Si convex portion (remaining portion) 106b having the maximum height a is etched and removed. As a result, the SiO₂ layer 102 may not sufficiently function as an etching stop layer. It has been confirmed in an experiment performed by the present inventors that the phenomenon tends to more readily occur as the area of a surface to be etched of an Si substrate 100 is larger.

On the other hand, to improve the performance of a transistor Tr to be formed, the BOX layer of an SOI device and the gate oxide film of a MOSFET are desirably formed to be as thin as possible. Furthermore, in recent years, a method capable of forming a very thin SiO₂ film having a good film quality has been established. The performance of the transistor Tr has increasingly improved and micropatterning has advanced. In addition, an intelligent semiconductor apparatus like a microcomputer (μC) including functional electronic elements such as transistors Tr at high density is increasingly developed. In these points, the above-described etching technique can provide a semiconductor apparatus with high production efficiency at low cost. Solving the above problem thus significantly develops the semiconductor industry.

The present invention has been made in consideration of the above points, and provides an etching method for a silicon-based semiconductor substrate in which an SiO₂ layer reliably functions as an etching stop layer even if fluonitroic acid having a high etching rate is used as an etching chemical solution.

The present invention also provides an etching method for a silicon-based semiconductor substrate which has very high productivity and can reliably undergo etching processing.

According to an etching method for a semiconductor product of the present invention, firstly, it is possible to provide a semiconductor product having a surface with high smoothness and flatness.

Secondly, it is possible to provide a semiconductor product having a surface with high smoothness and flatness for a photoelectric conversion module having a light incident surface which can efficiently, externally guide light to a photoelectric conversion unit.

Thirdly, it is possible to provide a semiconductor product having a surface with high smoothness and flatness for a back-side illumination image sensor with significantly improved production efficiency.

The present invention is based on the fact that the present inventors found, by repeatedly, carefully observing an etching state in a repeatedly performed experiment, that formation of undulating unevenness was associated with the supply position, supply amount, and flow direction of an etching solution, and the surface temperature of an etched surface had significant position dependence.

The present invention will be described in detail below with reference to the accompanying drawings, but is not limited to the following examples.

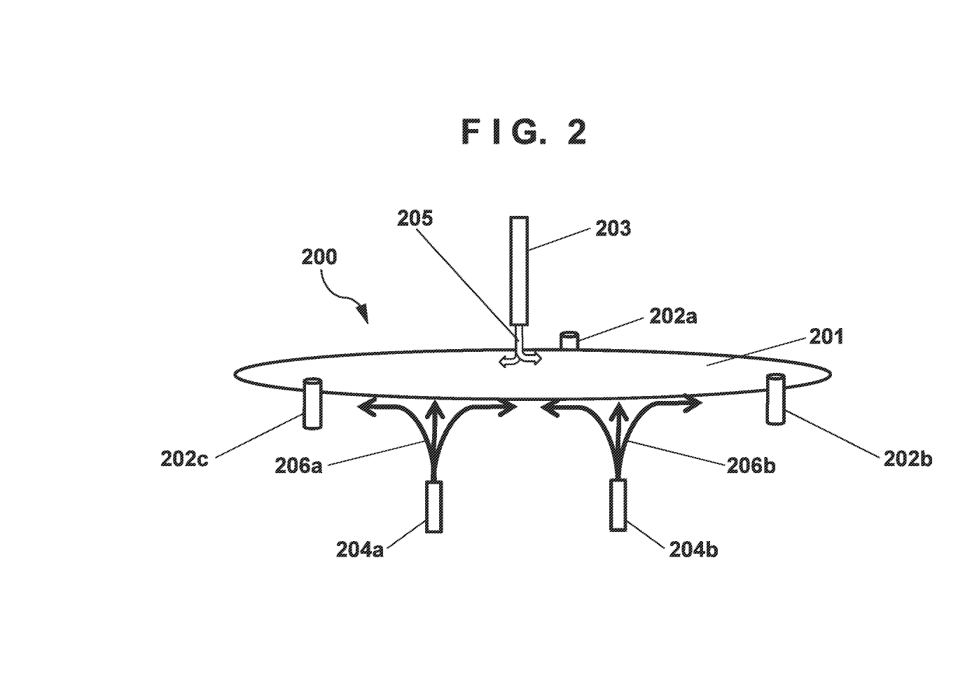

FIG. 2 is a schematic view for explaining the main parts of an example of an etching apparatus according to the present invention.

As shown in FIG. 2, an Si substrate 201 is arranged so that a nozzle 203 is positioned at the rotation center of the substrate 201, and is supplied with an etching chemical solution 205 from the nozzle 203 while rotating at a fixed speed. Furthermore, the Si substrate 201 is supported by substrate supporting means 202a, 202b, and 202c. Since the substrate 201 rotates at a fixed predetermined rotation speed, the etching chemical solution 205 supplied from the nozzle 203 to the etched surface of the substrate 201 flows on the etched surface of the substrate 201 in a spiral pattern toward the outer peripheral edge of the substrate 201 by the centrifugal force generated by the torque.

Since the etching reaction when etching the Si substrate by fluonitric acid is an exothermic reaction, the temperature of fluonitric acid may locally rise to as high as 100° C. An etching rate ER for Si of fluonitric acid depends on not only the concentration but also the temperature. As the temperature of the chemical solution rises, the etching rate ER also increases. In some cases, therefore, it is necessary to decrease the temperature of the chemical solution during etching processing. It is thus convenient to provide a nozzle 204 for supplying a coolant.

A coolant 206 may be a liquid or gas. Examples of the liquid are cold water and liquid nitrogen. An example of the gas is cooling air. In the apparatus shown in FIG. 2, the nozzle 204 discharges the coolant 206 toward the lower surface of the substrate 201. In FIG. 2, two nozzles 204a and 204b are provided as the nozzle 204 for supplying the coolant 206.

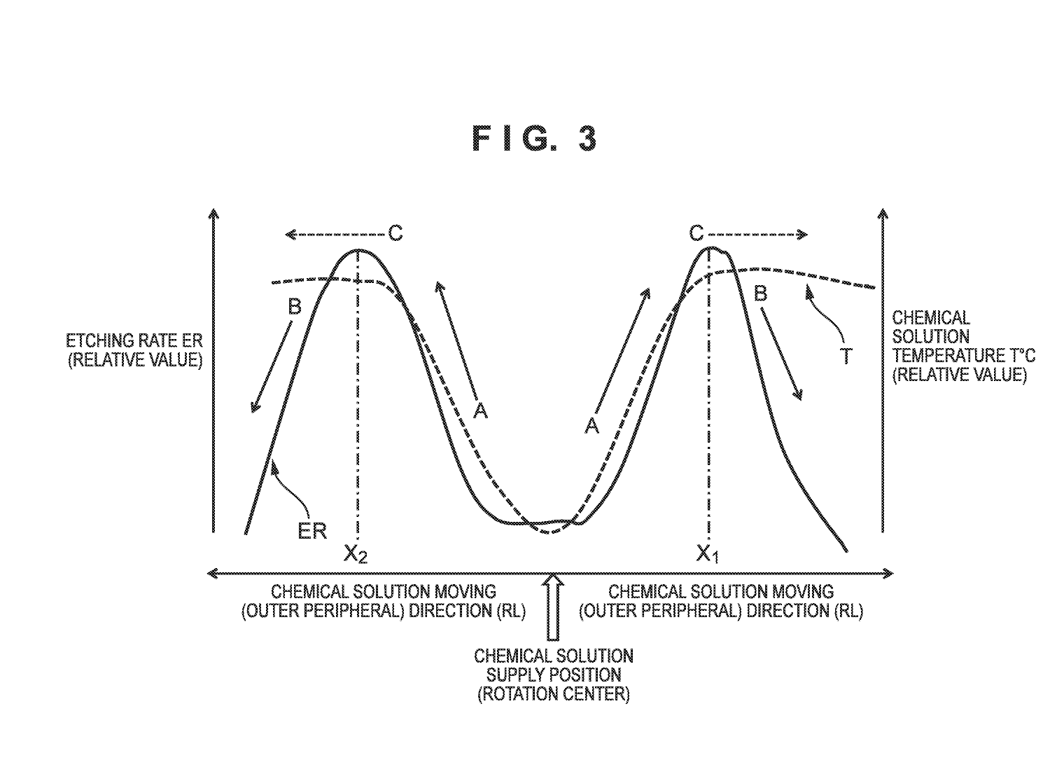

A typical simplest example when performing etching processing by supplying fluonitric acid of a predetermined concentration from the nozzle 203 of the apparatus shown in FIG. 2 will be described with reference to FIG. 3.

(1) Experimental Conditions
Position of nozzle 203 . . . on the rotation center axis of the substrate above the etched surface of the substrate
Etching chemical solution supply amount . . . 1 L/min
Rotation speed of sample (p-type Si substrate: 200 mmφ) . . . 850 rpm
Etching time . . . 15 sec
Etching chemical solution . . . fluonitric acid of HF:30%-HNO₃:28%
Temperature of upper surface of sample . . . measuring by a thermo camera

FIG. 3 shows a typical example of an obtained result. Referring to FIG. 3, the abscissa represents a position (the flow position of the chemical solution) from a chemical solution supply position (the rotation center of the substrate 201) in the outer peripheral direction of the Si substrate 201 (the radius direction of the substrate 201). The ordinate represents a relative value of the etching rate ER or the chemical solution temperature T (° C.). In FIG. 3, a solid line indicates the etching rate ER and a dotted line indicates the chemical solution temperature.

A region (a fixed ER region: the bottom center portion of the graph shown in FIG. 3) up to a given distance from the rotation center position of the Si substrate 201 (the chemical solution supply position of the nozzle 203) in the outer peripheral direction of the Si substrate 201 has an etching rate (ER) almost equal to that (ER) at the rotation center position. After passing through the region, there exists an ER rising region (A), as indicated by an arrow A, where the etching rate (ER) reaches its peak at a position X. It is understood from FIG. 3 that after passing through the peak position X, there exists an ER reducing region (B) as indicated by an arrow B, and the decrease in etching rate (ER) becomes moderate near the outer peripheral edge of the Si substrate 201.

As indicated by the dotted line, the solution temperature T in this case has a tendency similar to that of the etching rate ER from the rotation center of the substrate 201 to the position X. However, unlike the etching rate ER, the solution temperature T does not decrease and is almost flat even after passing through the position X.

Two peak positions X (X₁ and X₂) do not always coincide with each other even in absolute values. The peak positions may coincide with other, as a matter of course. Whether the peak positions coincide with each other is not essential to the present invention.

These etching rate regions, the ER curve shape, the peak value of the ER, the peak positions X, and the like depend on the rotation speed of the substrate 201 having an etched surface, the supply amount of the etching solution per unit time, the composition, composition ratio, concentration, viscosity and surface tension of the etching solution, the number, arrangement positions, orifice shape and discharge directions of the nozzles 203, and the like.

According to the present invention, an appropriate (flat) ER curve is obtained by adjusting the number, arrangement positions, orifice shape, discharge directions and the like of the nozzles 203, the composition ratio and concentration of fluonitric acid, the supply amount of the fluonitric acid chemical solution from the nozzles 203, a supply method, the rotation speed of the substrate 201, and the like, and/or changing/readjusting, during etching processing or when etching processing is stopped, some of the above parameters which can be changed/readjusted during etching processing or when etching processing is stopped.

In addition, immediately before or after the surface of the SiO₂ layer is exposed, the etching solution is changed from fluonitric acid having a high etching rate ER (high-ER fluonitric acid) to that having a low etching rate ER (low-ER fluonitric acid), thereby continuing the etching processing.

There are various methods of switching from high-ER fluonitric acid to low-ER fluonitric acid. In the present invention, for example, it is preferable to adopt a method of switching from high-ER fluonitric acid to low-ER fluonitric acid at an appropriate chemical solution supply timing by providing two types of chemical solution nozzles including a high-ER fluonitric acid nozzle and a low-ER fluonitric acid nozzle. For the apparatus shown in FIG. 2, it is preferable to eject the coolant from the nozzles 204 to the lower surface of the Si substrate 201 at an appropriate timing to quickly cool the Si substrate 201, thereby decreasing the temperature of the chemical solution on the Si substrate 201 and decreasing the etching rate ER. Alternatively, it is preferable to provide a cooling means in the nozzle 203 and/or midway along a supply pipe connected to the nozzle 203, and rapidly lower the temperature of the fluonitric acid chemical solution supplied from the nozzle 203 at a good switching timing, thereby instantaneously supplying the low-ER fluonitric acid chemical solution to the etched surface of the Si substrate 201.

A method of timing switching from the high-ER fluonitric acid to the low-ER fluonitric acid is selected, as needed, within a range in which the object of the present invention is effectively achieved. For example, it is desirable to select one of the following methods.

One method (switching timing acquisition method A and practice A of the present invention based on the method) is as follows.

(1) Data of the etching rate ER of an Si wafer to be used and the distribution of the etching rate ER are acquired in advance.

(2) When the surface of the SiO₂ layer is exposed for the first time during etching of the Si layer of the Si substrate (sample) by high-ER fluonitric acid, etching is temporarily stopped and a laser displacement gage is used to measure the remaining thickness (corresponding to the height a of FIG. 1) of an Si remaining portion remaining on the surface of the SiO₂ layer.

(3) A period of time (sec) during which it is necessary to perform etching processing by low-ER fluonitric acid in order to completely etch and remove the Si remaining portion and stop etching just before the surface of the SiO₂ layer under the Si remaining portion is calculated based on the result of measuring the remaining thickness of the Si remaining portion and the data of the concentration dependence of the etching rate.

(4) An etching experiment is performed by switching to low-ER fluonitric acid after etching by high-ER fluonitric acid based on the obtained calculated value, and whether the predetermined Si remaining portion has been completely removed and etching has been stopped just before the surface of the SiO₂ layer is confirmed using the laser displacement gage.

(5) After the above preparation, etching processing is actually performed for the Si substrate (the present invention is practiced) under the same conditions as those of the above experiment.

Another more preferable example (complete automation) will be described below.

A laser sensor probe (having a high chemical resistance) is provided in an etching processing chamber. During etching processing or immediately after etching processing, a change in thickness of the Si layer is monitored in line. When the Si layer is etched and removed by an amount which has been input to the central control unit in advance, high-ER fluonitric acid is instantaneously, automatically switched to low-ER fluonitric acid. The laser sensor probe is systematized so as to arbitrarily scan the upper surface of the Si substrate.

In addition to the above examples, the following examples are also preferable in the present invention.

That is, there is provided a method of performing etching while directly monitoring the thicknesses of the Si layer and SiO₂ layer by mounting an optical interference film thickness measurement apparatus in the etching processing chamber.

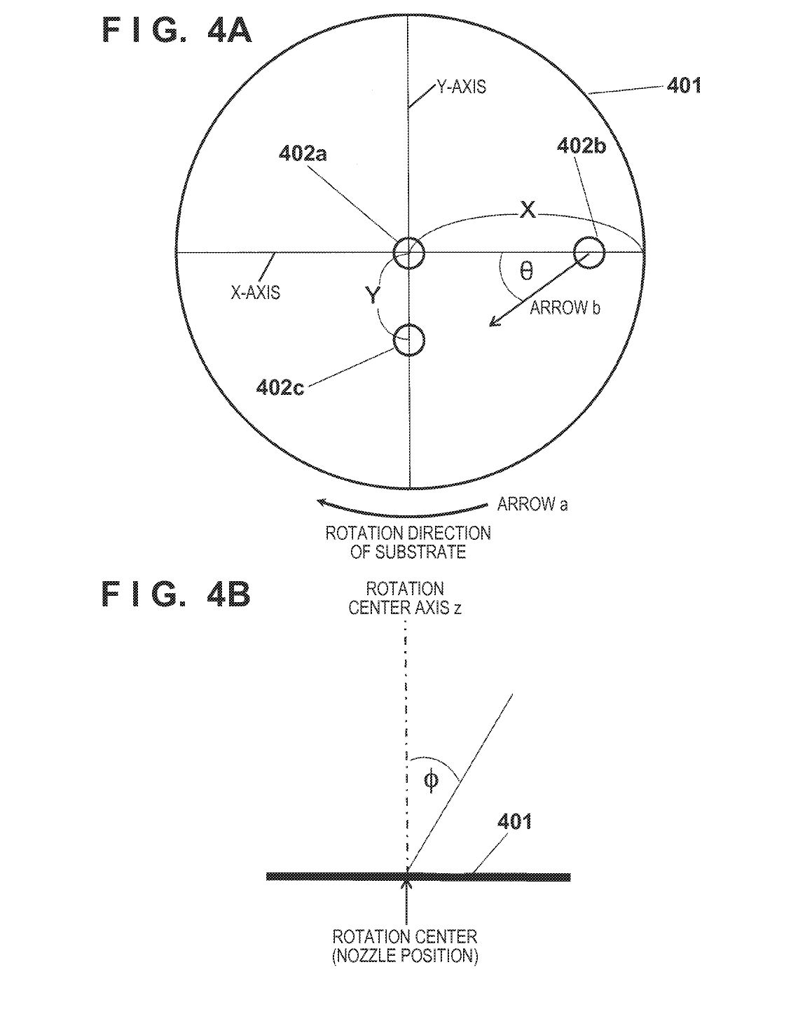

FIGS. 4A and 4B are schematic views for explaining the positional relationship between the respective nozzles, solution discharge directions from the nozzles (the orientations of the nozzles), and the like when performing etching by arranging the three nozzles at predetermined positions.

Each of three etching solution supply nozzles 402a, 402b, and 402c drops and supplies an etching solution to the etched processing surface of an Si substrate 401. The etching solution supplied from each nozzle is adjusted to a predetermined temperature and then supplied. The Si substrate 401 rotates at a desired rotation rate, as indicated by an arrow a. The etching solution is supplied to the etched processing surface of the Si substrate 401 while rotating the Si substrate 401 at a fixed speed. The position of the nozzle 402a coincides with the rotation center position of the Si substrate 401.

The etching solution dropped and supplied from each nozzle to the etched processing surface of the Si substrate 401 flows in the outer peripheral direction of the Si substrate 401 while drawing a spiral or arc-shaped locus in accordance with the rotation speed of the Si substrate 401. The locus of flowing of the etching solution becomes closer to a straight line as the rotation speed of the Si substrate 401 increases.

When the discharge direction of solution supply is set to be opposite to the rotation direction of the substrate, a solution layer on the rotating substrate swells in a portion where the supplied solution contacts the solution layer, thereby interfering with stable flow of the solution on the substrate. Since this interference may locally change the etching rate, it may be undesirable to set the discharge direction of solution supply to be opposite to the rotation direction of the substrate. The degree of the interference depends on the rotation speed of the substrate and the discharge speed/discharge angle of the solution. For this reason, it is desirable to select the rotation speed of the substrate and the discharge speed/discharge angle of the solution so that the influence of the interference causes substantially no local change in etching rate. It is particularly preferable to set the discharge direction to be parallel to the rotation direction of the substrate.

It is preferable to set the solution discharge direction from the orifice of the nozzle 402b to a direction indicated by an arrow b at an angle θ with respect to the X-axis since interference with flow of the etching solution on the upper surface of the substrate 401 can be reduced to a minimum. It is desirable that the angle θ preferably falls within the range of 0°<θ<90°, and more preferably falls within the range of 10°≦θ≦45°. The solution discharge direction from the orifice of the nozzle 402b is set to a predetermined direction while keeping an angle φ with respect to the Z-axis in terms of the relationship with a rotation center axis Z and keeping the angle θ with respect to the X-axis in terms of the relationship on the X-Y plane. The angle φ is set to an appropriate value in terms of the relationship with the angle θ, the shape and size of the nozzle 402, the shape, size, and number of the orifices of the nozzle 402, and the rotation speed of the substrate 401 so as to effectively achieve the object of the present invention.

Referring to FIGS. 4A and 4B, the three nozzles are arranged above the Si substrate 401 at a predetermined distance from the etched surface (upper surface) of the Si substrate 401. That is, the nozzle 402a is arranged at a position which coincides with the rotation center of the Si substrate 401, the nozzle 402b is arranged at a position on the X-axis, and the nozzle 402c is arranged at a position on the Y-axis. The nozzles 402a and 402b are arranged to have a distance X between them. The nozzles 402a and 402c are arranged to have a distance Y between them.

In the easiest arrangement, etching (chemical) solution discharge directions from the three nozzles 402 toward the substrate 401 are set to be perpendicular to the upper surface of the substrate 401. In this case, an appropriate solution supply amount per unit time from each of the three nozzles 402 is determined in consideration of the rotation speed and size of the substrate 401. If the size of the substrate 401 is not so large, it may be possible to appropriately supply the solution using only the nozzle 402a.

The distances X and Y depend on the shapes and sizes of the nozzles 402 and the shapes, sizes, and number of orifices of each nozzle 402, and are designed to effectively achieve the object of the present invention. The shape and orifice structure, the solution discharge force, and the discharge direction of each nozzle influence the fluidity of the etching solution on the substrate. When the degree of the influence exceeds a certain degree, the etching rate may change. It is, therefore, desirable to appropriately select the shape and orifice structure, the solution discharge strength, and the discharge direction of each nozzle so as to achieve the object of the present invention.

Although the shape of each nozzle may be linear, tapered narrower to the end, or tapered wider to the end, it is preferably tapered narrower to the end since it then becomes possible to readily obtain more correct discharge directivity. The nozzle array may be a single-row array, multi-row array, or concentric circle array as long as it is designed to achieve the object of the present invention. Furthermore, a method of discharging an etching chemical solution from a plurality of nozzles may be of a divergent type, a directional type, or a convergent type like a so-called shower head. Increasing the discharge pressure by decreasing the orifice area of the nozzle is also effective to improve the directivity of the solution supply direction.

A chemical solution may be supplied to the etched surface of the Si substrate by a pressure-feeding method, pressurization method, gravity drop method, vertical discharge supply method, pressurized drop method, or inclination discharge method.

It is desirable that the angle φ preferably falls within the range of 90°≧φ>0°, and more preferably falls within the range of 60°≧φ≧10°.

The etching rate largely depends on the concentration of a chemical constituent material of the etching solution, which determines the degree of the exothermic reaction occurring in etching. The present invention has as its one object to prevent a big etching rate difference shown in the typical example of FIG. 3 in the temperature distribution of the etched surface of the substrate undergoing etching processing when practicing the present invention.

In the present invention, even if fluonitric acid generally used and having a general stoichiometric composition ratio and concentration is used, it is possible to obviously obtain the effect of the present invention. However, fluonitric acid having the following stoichiometric composition ratio and concentration is preferably used from the technical viewpoint of high mass productivity such that the etching rate is significantly high and the effect of the present invention is dramatic.

That is, the values of a, b, and c of the expression presented earlier are selected to obtain a desired etching rate at which it is possible to manufacture a target Si substrate with high productive efficiency, as needed.

According to the present invention, in general, the values of a, b, and c desirably fall within the ranges of 19≦a≦42, 11≦b≦60, and 28≦c≦45, respectively, where a+b+c=100. Under these conditions, it is possible to ensure at least an etching rate of 400 μm/min for the Si substrate.

Preferably, the values desirably fall within the ranges of 23≦a≦40, 14≦b≦52, and 25≦c≦46, respectively, where a+b+c=100. Under these conditions, it is possible to ensure at least an etching rate of 600 μm/min for the Si substrate.

More preferably, the values desirably fall within the ranges of 27≦a≦37, 18≦b≦45, and 28≦c≦45, respectively, where a+b+c=100. Under these conditions, it is possible to ensure at least an etching rate of 800 μm/min for the Si substrate.

Note that the unit of a, b, and c of the above expressions is wt %.

According to the present invention, more preferably, c≦a+b holds in addition to the above conditions.

According to the present invention, as long as the values of a, b and c of HF (a)-HNO₃ (b)-H₂O (c) and their relationship are defined as described above, and there is no practical adverse effect on the etching rate, a necessary additive may be added depending on the purpose. Examples of the additive are acetic acid, sulfuric acid, and phosphoric acid.

[Experiment 1]

The temperature dependence of an etching rate was confirmed as follows. A general etching apparatus was used as a laboratory apparatus.

A dipping tank stored fluonitric acid of a predetermined concentration as an etching chemical solution. The dipping tank was arranged in a thermostatic chamber. The etching chemical solution in the dipping tank was kept at a predetermined temperature. The dipping tank included a magnetic stirrer for keeping the temperature of the etching chemical solution uniform by being externally applied with a torque to stir the etching chemical solution in the dipping tank. A silicon wafer serving as an experimental sample was dipped into the dipping tank prepared as described above, and underwent an etching experiment.

Experimental conditions will be described below.

(1) Preparation of Sample and Chemical Solution
Sample . . . p-type silicon wafer substrate having a side of 30 mm and a thickness of 775 μm
Etching chemical solution . . . fluonitric acid chemical solution of a predetermined concentration (the concentration of HNO₃ was adjusted within the range of 4 to 49 wt % and the concentration of HF was adjusted within the range of 13.5 to 47 wt %)

(2) Etching Manner
Etching method . . . dipping method
Etching surface . . . both surfaces
Etching time . . . 20 sec to 1 min
Sample 403 was oscillated in the chemical solution (oscillation cycle: 1.5 sec/reciprocation)

(3) Measurement of Etching Rate
Measurement method . . . laser thickness measuring gage (accuracy: 1 μm)
a half of the difference in thickness of the wafer before and after etching

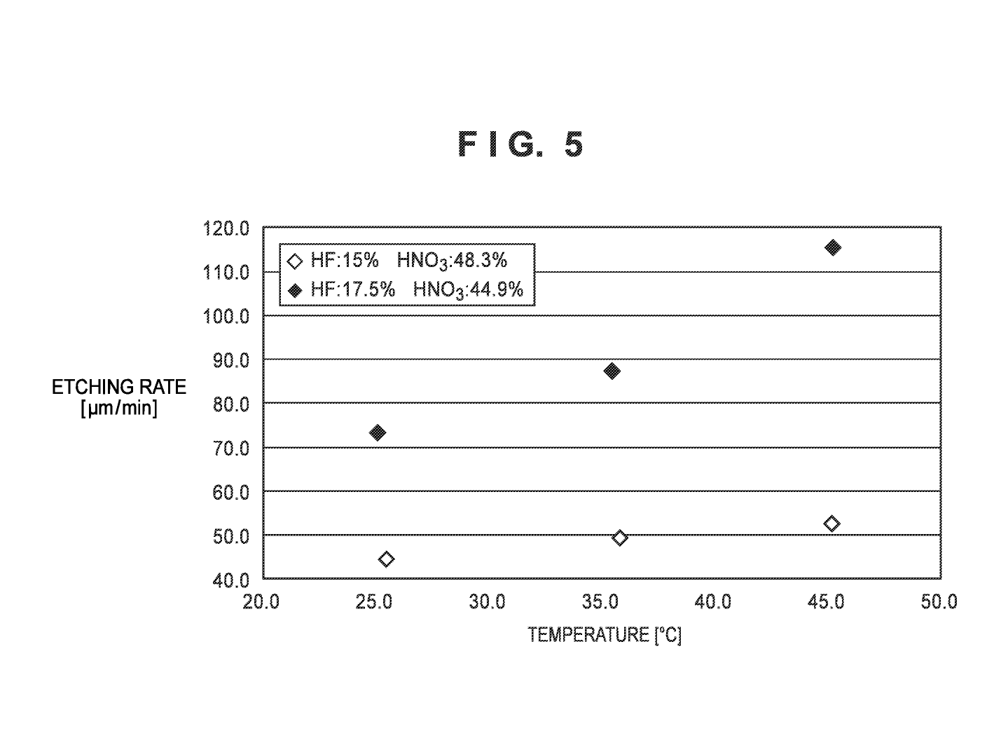

FIG. 5 shows the result. It is apparent from FIG. 5 that as the concentration of the etching chemical solution is higher, the temperature dependence of the etching rate is also higher.

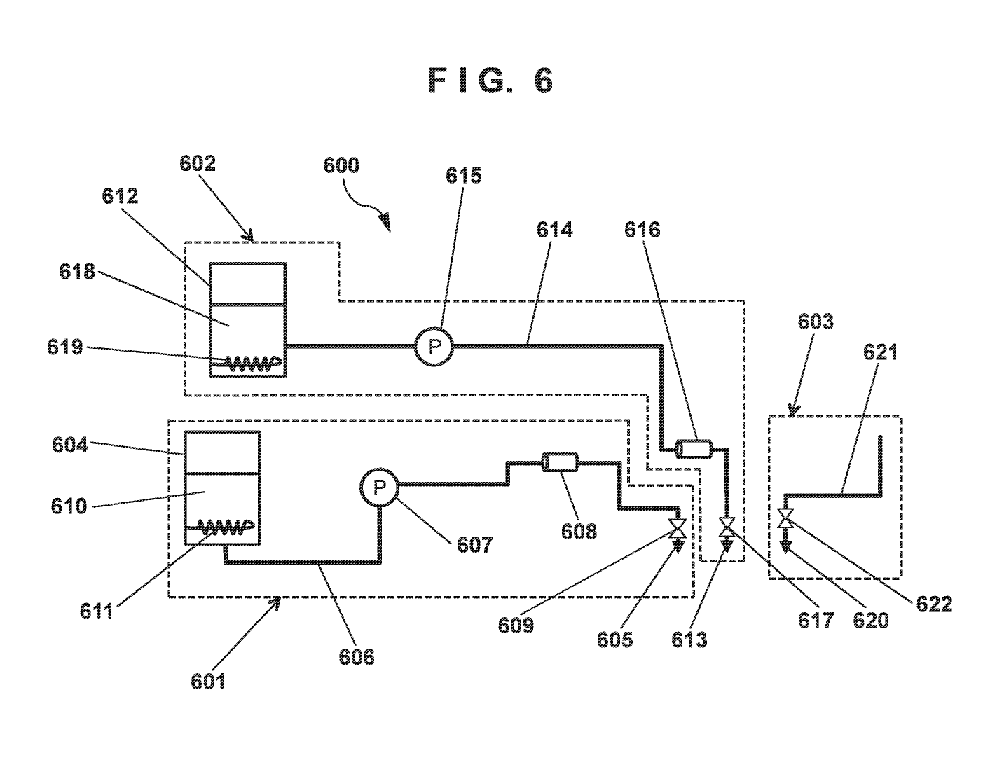

FIG. 6 is a schematic view for explaining one preferred example of the etching apparatus used to practice the present invention.

An etching apparatus 600 shown in FIG. 6 includes three subsystems. The first and second subsystems are systems each for supplying a fluonitric acid chemical solution. A chemical solution supply subsystem 601 is used to supply a high-ER fluonitric acid chemical solution and a chemical solution supply subsystem 602 is used to supply a low-ER fluonitric acid chemical solution.

The chemical solution supply subsystem 601 includes a tank 604 for storing a chemical solution and a nozzle 605 for discharging the chemical solution, which are connected to each other by a chemical solution supply line 606. A pump 607 and a cooling means 608 are provided along the chemical solution supply line 606.

A heater 611 for heating a chemical solution 610 to a predetermined temperature is arranged in the tank 604. The pump 607 is used to supply the chemical solution to the nozzle 605 through the chemical solution supply line 606 at a predetermined pressure, and is configured to adjust the discharge pressure and the discharge amount per unit time of the chemical solution discharged from the nozzle 605. It is also possible to adjust the discharge amount per unit time to discharge a desired chemical solution amount by adjusting the opening/closing amount of a valve 609.

The cooling means 608 serves as an instantaneous cooling means which can instantaneously cool the chemical solution supplied to the nozzle 605, and is configured to instantaneously cool the high-temperature chemical solution supplied so far to a low-temperature, and supply the chemical solution from the nozzle 605. In the present invention, the means using a coolant, which has been explained with reference to FIG. 2, is preferably adopted as the cooling means 608. Alternatively, a cooling fan, cooling pump, Peltier device, or the like may be used.

The chemical solution supply subsystem 602 includes the same means and functions as those of the chemical solution supply subsystem 601 except that low-ER fluonitric acid 618 is supplied instead of the high-ER fluonitric acid 610.

In this regard, similarly to the chemical solution supply subsystem 601, the chemical solution supply subsystem 602 includes a tank 612, a nozzle 613, a pump 615, a chemical solution supply line 614, a cooling means 616, valve 617, and a heater 619. The tank 612 stores the low-ER fluonitric acid 618.

A cleaning subsystem 603 is used to clean the etched surface of the semiconductor product by ultrapure water, as needed. The cleaning subsystem 603 includes at least a nozzle 620, a cleaning solution supply line 621, and a valve 622.

### Preferred Embodiment

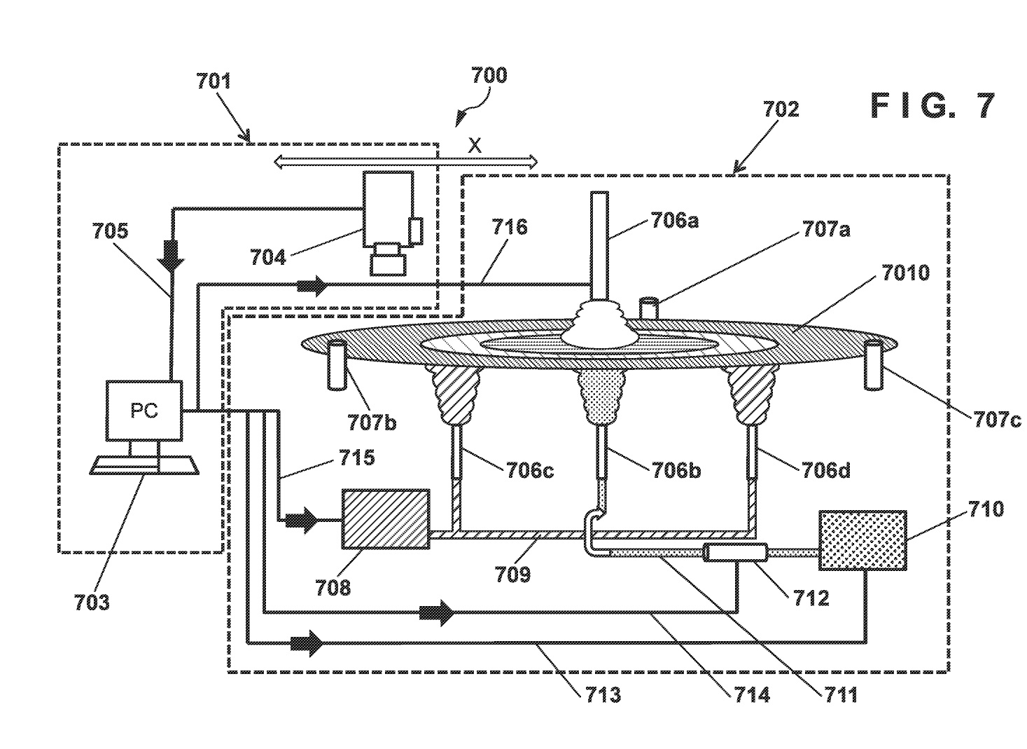

FIG. 7 shows a preferred embodiment of an etching system used to practice the present invention.

An etching system 700 shown in FIG. 7 includes a subsystem 701 and an etching apparatus main body 702.

The subsystem 701 includes a central control unit 703 and a laser sensor probe 704. In the subsystem 701, the laser sensor probe 704 measures an etching status all the time and the thus obtained data is transferred to the central control unit 703 through a data transfer line 705. A control signal generated by the central control unit 703 based on the transferred data is transferred through a control signal transfer line 716 to control a chemical solution discharge control means (not shown) attached to a nozzle 706a. One or both of the temperature and discharge amount of a chemical solution discharged from the nozzle 706a are automatically controlled. The timing of switching the chemical solution is also controlled according to the control signal.

The apparatus main body 702 includes the nozzle 706a for supplying the etching chemical solution, a nozzle 706b for discharging a heating solution, two nozzles 706c and 706d for discharging a cooling solution, three supporting means 707a, 707b, and 707c for supporting the Si substrate 7010 to undergo etching processing, a tank 708 for storing the cooling solution, a supply line 709 for supplying the cooling solution, a tank 710 for storing the heating solution, a supply line 711 for supplying the heating solution, and an instantaneous heating means 712.

Each of transfer lines 713, 714, and 715 for transferring a control signal is connected to a control target. The transfer line 713 transfers a signal to keep the solution in the tank 710 as its control target at a predetermined heating temperature. A signal transferred by the transfer line 714 controls the instantaneous heating means 712. This control operation can instantaneously control the temperature of the heating solution supplied by the supply line 711 based on the measurement data of the laser sensor probe 704, thereby keeping the temperature of the etched surface of the substrate 7010 during etching processing free of position dependence. The control signal transferred by the transfer line 715 instantaneously controls the temperature of the cooling solution in the tank 708 at a predetermined temperature.

### Example

The etching system 700 performed etching processing under the following conditions.

The etching processing conditions were as follows.
Etched sample . . . p-type Si wafer (substrate)
Etching chemical solution . . . fluonitric acid of HF/30%:HNO₃/28%
Chemical solution nozzle position and chemical solution supply . . . arrangement on the center axis and vertical drop and supply
Chemical solution supply amount . . . 5 L/min
Substrate rotation count . . . 800 rpm
Control temperature . . . reaction temperature controlled at 85° C.
Experiment time . . . 45 sec

Upon completion of etching, the sample was rinsed by UPW (ultrapure water) at 5 L/min for 10 sec. Upon completion of the rinse, the remaining thickness of the wafer was measured by the laser sensor probe. As a result, the remaining thickness of a portion etched the most was about 2 μm to the SiO₂ layer.

After that, etching was performed under the following conditions.
Etched sample . . . p-type Si wafer (substrate)
Etching chemical solution . . . fluonitric acid of HF/15%:HNO₃/43.8%
Chemical solution nozzle position and chemical solution supply . . . arrangement on the center axis and vertical drop and supply
Chemical solution supply amount . . . 3 L/min
Substrate rotation count . . . 800 rpm
Control temperature . . . reaction temperature controlled at 30° C.
Experiment time . . . 30 sec

Upon completion of etching, the sample was rinsed by UPW (ultrapure water) at 5 L/min for 10 sec. By observing the etching surface, it was found that a very wide range (near the outer peripheral edge of the substrate) of the surface of the SiO₂ layer was exposed, and the SiO₂ layer had no completely SiO₂ depleted portion or Si remaining portion. With this fact, the effect of the present invention could be confirmed.

[Modification]

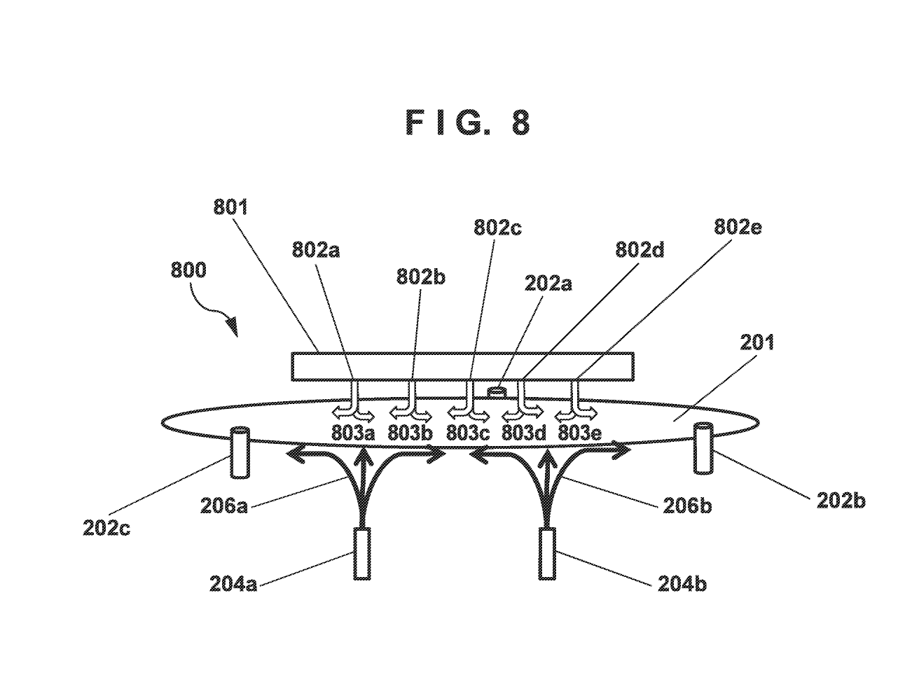

FIG. 8 shows a modification of the etching apparatus shown in FIG. 2. An etching apparatus 800 is substantially the same as that shown in FIG. 2 except that a nozzle bar 801 is provided instead of the nozzle 203 of the apparatus shown in FIG. 2. The nozzle bar 801 includes five orifices 802a to 802e, from which chemical solutions 803a to 803e each having a desired concentration and temperature are discharged, respectively.

The orifices 802 are horizontally arranged in line in the diameter direction of the substrate 201. In the present invention, the array of the orifices is not limited to this. The array of the orifices is designed as a multi-row array or staggered array, as needed. The array pitches of the orifices are designed to be equal, unequal, or spreaded, as needed, depending on the purpose.

The present invention is not limited to the above-described embodiments, and various changes and modifications can be made within the spirit and scope of the present invention. Therefore, to apprise the public of the scope of the present invention, the following claims are made.

### REFERENCE SIGNS LIST

100, 201 . . . Si substrate
101 . . . Si wafer substrate
102 . . . SiO₂ layer
103 . . . Si layer
104 . . . surface of SiO₂ layer
105 . . . exposed surface of SiO₂ layer
106 . . . Si remaining portion
107 . . . surface of Si layer
200 . . . etching apparatus
202 . . . supporting means
203, 204 . . . nozzle
205 . . . discharge chemical solution
206 . . . coolant
401 . . . substrate
402 . . . nozzle
600 . . . etching apparatus
601, 602 . . . chemical solution supply subsystem
603 . . . cleaning solution supply subsystem
604, 612 . . . tank
605, 613, 620 . . . nozzle
606, 614 . . . chemical solution supply line
607, 615 . . . pump
608, 616 . . . cooling means
609, 617, 622 . . . valve
610, 618 . . . chemical solution
611, 619 . . . heater
621 . . . cleaning solution supply line
700 . . . etching system according to present invention
701 . . . subsystem
702 . . . apparatus main body
703 . . . central control unit
704 . . . laser sensor probe
705 . . . data transfer line
706 . . . nozzle
707 . . . supporting means
708, 710 . . . tank
709 . . . cooling solution supply line
711 . . . heating solution supply line
712 . . . instantaneous heating means
713, 714, 715, 716 . . . control signal transfer line

What is claimed is:

1. An etching method for a semiconductor product comprising:
preparing the semiconductor product having, on a substrate, an SiO₂ layer, and an Si layer with a free surface and directly stacked on the SiO₂ layer; and
etching the Si layer while supplying an etching solution from a side of the free surface using high-concentration fluonitric acid as the etching solution, and continuing etching by switching to fluonitric acid having a concentration lower than that of the fluonitric acid immediately before or after at least part of a surface of the SiO₂ layer immediately under the Si layer is exposed.

2. The etching method for the semiconductor product according to claim 1, further comprising measuring a temperature at a plurality of predetermined positions on the surface during the etching; and heating or cooling the surface in accordance with the measured values.

3. An etching method for a semiconductor product, comprising:
performing etching processing while supplying a fluonitric acid solution to a surface of an Si layer of the semiconductor product having, on a substrate, an SiO₂ layer and the Si layer with a free surface and directly stacked on the SiO₂ layer, the etching processing comprises:
a first step of performing etching processing for the surface of the substrate using first fluonitric acid having a chemical composition of HF (a)-HNO₃ (b)-H₂O (c) (a+b+c=100 and a+b≧50 where a, b, and c are numerical values each representing a concentration, and the unit of a, b, and c is wt %) until a time immediately before or after at least part of the surface of the SiO₂ layer is exposed; and
a second step of, after the first step, continuing etching processing using second fluonitric acid having a concentration lower than that of the first fluonitric acid.

4. The etching method for the semiconductor product according to claim 3, further comprising measuring a temperature at a plurality of predetermined positions on an etched surface of the Si layer during the etching processing; and heating or cooling the surface in accordance with the measured values.

5. An etching method for a semiconductor product, comprising:
measuring a temperature at a plurality of predetermined positions on the surface during the etching processing in which an exothermic reaction occurs while supplying an etching solution to a surface of an Si layer of the semiconductor product having, on a substrate, an SiO₂ layer and the Si layer with a free surface and directly stacked on the SiO₂ layer; and
heating or cooling the surface in accordance with the measured values, and switching from a high-concentration etching chemical solution to a low-concentration etching chemical solution immediately before or after at least part of the surface of the SiO₂ layer is exposed.
